(19) United States
(12) Patent Application Publication
(10) Pub. No.: US 2008/0159438 A1
(43) Pub. Date: Jul. 3, 2008

(54) METHODS AND APPARATUS FOR MULTI-MODE FREQUENCY SHIFT KEYING

(75) Inventors: Joseph M. Kulinets, North Andover, MA (US); Peter R. Nuytkens, Melrose, MA (US)

Correspondence Address: GOODWIN PROCTER LLP;PATENT ADMINISTRATOR, EXCHANGE PLACE, BOSTON, MA, 02109-2881, US

(73) Assignee: Custom One Design, Inc., Melrose, MA (US)

(21) Appl. No.: 11/961,987

(22) Filed: Dec. 20, 2007

Related U.S. Application Data
(60) Provisional application No. 60/876,190, filed on Dec. 20, 2006.

(51) Int. Cl. H04L 27/12; H03C 3/00

(52) U.S. Cl. 375/306; 332/100

(57) ABSTRACT

Methods and apparatus for signal transmission utilizing directly modulated frequency shift keying. Embodiments of the present invention provide a fractional (non-integer) N oscillator to directly modulate a baseband signal for transmission using a programmable digital raised cosine generator, providing a tunable Gaussian FSK transmitter.

### CROSS-REFERENCE TO RELATED APPLICATIONS

This application claims the benefit of U.S. Provisional Patent Application No. 60/876,190, filed on Dec. 20, 2006, which is hereby incorporated by reference as if set forth herein in its entirety.

### FIELD OF THE INVENTION

The present invention relates to methods and apparatus for data communications, and in particular to the use of frequency shift keying for data communications.

### BACKGROUND OF THE INVENTION

Frequency shift keying (FSK) is a form of digital frequency modulation using a transmitted signal that varies between two predetermined frequencies. A stream of digital data, i.e., consisting of digital ones and zeroes, is converted into a train of unitary pulses of opposite sign. For example, a digital one may be represented by a positive pulse and a digital zero may be represented by a negative pulse. Once converted, the pulse train is used to frequency modulate a baseband signal and the resulting modulated signal is then transmitted.

However, a baseband signal modulated using a train of square pulses may suffer from sharp transitions appearing as high-frequency noise in the modulated signal. This can cause such undesirable effects as adjacent channel interference and inter-symbol interference from multi-path signal reflections. One method known to the prior art to reduce these sharp transitions is to use a train of Gaussian pulses instead of square pulses, i.e., Gaussian frequency shift keying (GFSK). This may be performed, for example, by constructing a train of square pulses and then filtering the pulse train using a Gaussian filter.

One drawback to this GFSK approach is that it requires one filter for each frequency modulation scheme. While this may be acceptable for a single-mode transmitter, it can become unwieldy and expensive to implement in a multi-mode transmitter.

Accordingly, there is a need for methods and apparatus that provide improved FSK techniques for use, e.g., in the context of a multi-mode transmitter.

### SUMMARY OF THE INVENTION

The present invention addresses the shortcomings of existing FSK techniques by providing a fractional (non-integer) N oscillator to directly modulate a baseband signal for transmission using a programmable digital raised cosine generator, providing a tunable Gaussian FSK transmitter.

In one aspect, the present invention provides a digitally controlled modulator. The modulator includes a phase detector receiving a reference frequency signal and a feedback signal and providing a phase difference output. This output signal controls a charge pump circuitry inside the modulator whose output signal goes to a low-pass filter. The modulator also includes a voltage-controlled oscillator receiving the output signal from the low-pass filter as a frequency control signal and providing its frequency output signal as a divider clock signal. The modulator further includes a divider receiving the divider clock signal and a modulation signal, which represents the changing division ratio coefficient, and providing the end of division signal as the feedback signal. The modulation signal is varied between consecutive integer values so as to realize a divider input signal that on average is a non-integer, producing an output VCO frequency that is a non-integer multiple of the reference frequency, forming a so-called fractional-N phased locked loop. The reference frequency signal may be derived from, e.g., a thermally-controlled oscillator.

In one embodiment, the modulation signal is varied between consecutive integer values approximating stitched together parabolic curves. The modulation signal is a sum of two integer values: a constant value representing the integer part of non-integer N, and a changing value from the output of a sigma-delta modulator where the input signal of the sigma-delta stage is an output of a second adder. The inputs of the second adder may be, for example, a constant, representing the fractional part of a non-integer N, and another digital signal from the output of a raised cosine generator changing according to an approximation of a raised cosine law using two stitched-together parts of parabolas that are in a point symmetry to each other.

In one embodiment, the sigma-delta modulated signal is provided by a sigma-delta stage. The sigma-delta stage may be, e.g., at least third order. The input signal for the sigma-delta stage is provided by a digital summing circuit (adder) receiving as inputs the fractional part of non-integer N and an output signal from the raised cosine generator, and providing an output sum to the sigma-delta stage. The raised cosine generator may include a first integrator, a second integrator, and a control block.

In another aspect, the present invention provides a method for direct modulation. The method includes converting a reference signal and a feedback signal into a phase difference output signal using a phase detector, applying this signal to a charge pump circuitry, supplying the output signal of the charge pump to a low-pass filter; controlling a voltage-controlled oscillator (VCO) with the output signal from the low-pass filter, and providing an output frequency signal from the VCO as a clock signal for a divider. The method also includes applying to the divider a modulation signal serving as a changing division ratio coefficient, and supplying the end of the division signal as the feedback signal to the phase detector.

The method uses the varying of the modulation signal between consecutive integer values so as to realize a divider with a division ratio that on average is a non-integer multiple of the reference frequency, forming a so-called fractional-N phased locked loop.

The method further involves getting the modulation signal by adding the constant value representing the integer part of non-integer N, and the changing value from the output of a high order sigma-delta modulator, which is a sequential integer representing the results of a sigma-delta modulation of a fractional part of a non-integer N. The method may include deriving the reference signal from a thermally-controlled oscillator.

In one embodiment of the method proposed, the changing value from the output of the high order sigma-delta modulator is a sequence of integers representing the results of a high-order sigma-delta modulation of a sum of a constant, representing the fractional part of a non-integer N, and another digital signal changing according to a raised cosine law or its approximation and received from the output of a raised cosine generator. In another embodiment of the method proposed, the raised cosine generator uses a parabolic approximation of the raised cosine by stitching together two parts of parabolas that are in a point symmetry to each other. In still another embodiment of the method proposed, the raised cosine generator using the parabolic approximation of the raised cosine by stitching together two parts of parabolas that are in a point symmetry to each other has a first integrator, a second integrator, and a control block, and such parameters of the raised cosine as its magnitude and total duration are externally programmable.

In still another aspect, the present invention provides a method for direct modulation. The method includes converting a reference signal and a feedback signal into a phase difference output using a phase detector, providing a divider input signal from the phase difference output using a voltage-controlled oscillator, converting the divider input signal and a modulation signal into the feedback signal using a divider, and varying the modulation signal between consecutive integer values so as to realize a divider input signal that is a non-integer multiple of the reference frequency. The method may include deriving the reference signal from a thermally-controlled oscillator.

In one embodiment, varying the modulation signal comprises varying the modulation signal between consecutive integer values using stitched together parabolic curves. In another embodiment, the method further includes providing a filtered output from the phase difference output using a filter. In still another embodiment, the method further includes receiving the divider input signal at an antenna. In these embodiments, the method may further include receiving the divider input signal from the voltage-controlled oscillator at a power amplifier and providing the divider input signal to the antenna. In embodiments having a filter, the method may include receiving the phase difference output from the phase detector at a charge pump and providing the phase difference output to the filter.

In one embodiment, the method may include providing the modulation signal using a sigma-delta stage, e.g., of at least third order. In these embodiments, the method may include providing the modulation signal at the input of a sigma-delta stage using an adder circuit receiving inputs representing the fractional part of the required division value and an output value from the raised cosine generator, and providing a summed output as the modulation input signal. Providing the modulation input signal may include providing a sum of inputs representing fractional part of the required division value and an output value from the raised cosine generator, the raised cosine generator comprising a first integrator, a second integrator, and a control block.

The foregoing and other features and advantages of the present invention will be made more apparent from the description, drawings, and claims that follow.

### BRIEF DESCRIPTION OF DRAWINGS

The advantages of the invention may be better understood by referring to the following drawings taken in conjunction with the accompanying description in which:

FIG. 1 is a block diagram of an exemplary FSK transmitter for use in embodiments of the present invention;

FIG. 2 presents a block diagram of a model fractional (non-integer) N oscillator for use with an FSK transmitter in accord with the present invention;

FIG. 3A depicts an example of a raised cosine generator for use with an FSK transmitter in accord with the present invention;

FIG. 3B presents the signals associated with the raised cosine generator of FIG. 3A;

FIG. 4 illustrates an example of a Manchester encoded signal produced by the transmitter of the present invention.

FIGS. 5A & 5B present a flowchart of a method for FSK encoding in accord with the present invention; and

FIG. 6 presents a flowchart of another method for FSK encoding in accord with the present invention.

In the drawings, like reference characters generally refer to corresponding parts throughout the different views. The drawings are not necessarily to scale, emphasis instead being placed on the principles and concepts of the invention.

### DETAILED DESCRIPTION OF THE INVENTION

Embodiments of the present invention provide a tunable FSK transmitter suited for various communication applications using a fractional (non-integer) N oscillator to directly digitally modulate a baseband signal for transmission.

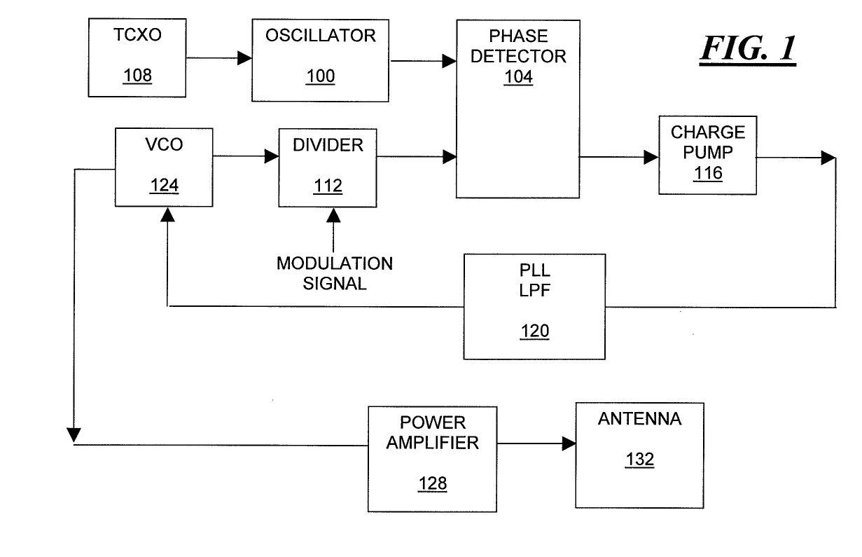

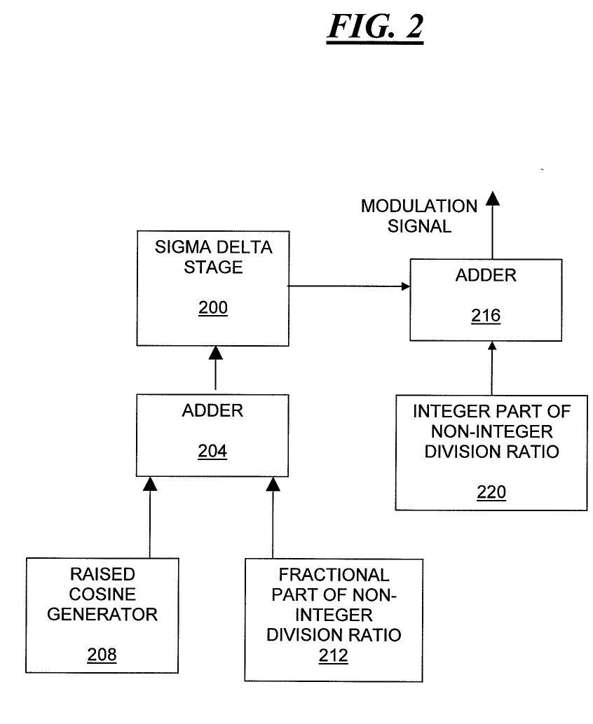

FIG. 1 presents an FSK transmitter for use in embodiments of the present invention. Oscillator 100 provides a pulse train signal as a reference frequency signal to phase detector 104. A thermally-compensated crystal oscillator (TCXO) 108 is coupled to the oscillator 100 to stabilize the frequency of oscillation. The thermally-compensated aspect of TCXO 108 helps ameliorate the crystal's natural tendency to slow down when the ambient temperature deviates from the crystal's intended temperature of operation.

The phase detector 104 receives a second pulse train from divider 112 and compares it to the reference pulse train received from the oscillator 100. The output of phase detector 104 is a voltage signal that represents the difference in phase between the reference pulse train and the second pulse train. The charge pump 116 receives the output of phase detector 104 and operates to change the voltage level of the phase detector output so that it may be used by the phase locked loop/low-pass filter (PLL/LPF) 120.

The low-pass filter serves to reduce or eliminate high frequency noise from the output of the charge pump 116. The phase-locked loop generates a signal that varies until it matches the input to the PLL/LPF 120 in both frequency and phase.

The output of PLL/LPF 120 is provided as a frequency control signal input to voltage-controlled oscillator (VCO) 124, which in turn provides a frequency modulated signal that is amplified by power amplifier 128 and broadcast through antenna 132. The output of the VCO 124 is also provided as a clock input to the divider 112, which multiplexes it with a modulation signal (discussed in greater detail below), before providing the end of division signal as a feedback input to phase detector 104.

In operation, the circuit of FIG. 1 transmits an FSK modulated signal at frequencies that reflect the modulation signal provided as an input to divider 112. This modulation signal represents the changing division ratio coefficient. When the modulation signal is a fixed digital number, then the frequency of the VCO 124 is a fixed integer multiple of the reference frequency provided by the TCXO 108, and more specifically the sum of two integer values: a constant value representing the integer part of non-integer N and a changing value from the output of a higher-order sigma-delta modulator, i.e., a sequential integer representing the results of sigma-delta modulation of a fractional part of non-integer N. Direct modulation of the broadcast signal using the modulation signal injected at divider 112 effectively results in a tunable FSK transmitter.

When the modulation signal alternates between adjacent integer values (e.g., N, N+1, N+1, N, N+1, N+1, etc.), the frequency on average of the VCO 124 and, accordingly, the broadcast frequency, is a non-integer multiple of the reference frequency provided by the TCXO 108. With reference to FIG. 2, one way to provide such a modulation signal and, accordingly, a fractional N output, is to use a sigma-delta modulator, such as a third-order sigma-delta modulator. By changing the sequence emitted by the sigma-delta modulator 200, the voltage provided to VCO 124 is changed and the frequencies used for FSK transmission are likewise changed.

As depicted in the embodiment of FIG. 2, the main source of the modulation signal is sigma-delta stage 200 that is configured to receive its input from an adder 204 that sums the output of a raised cosine generator 208 with the fractional part of a non-integer division ratio 212. The output of the sigma-delta stage 200 is in turn provided to another adder 216 that sums the output of the sigma-delta stage 200 with the integer part of a non-integer division ratio 220. The result is that sigma-delta stage 200 provides a pulse train with edges that approximate a Gaussian curve using, e.g., two stitched parabolic curve parts that are in a point symmetry to each other, providing Gaussian FSK transmissions.

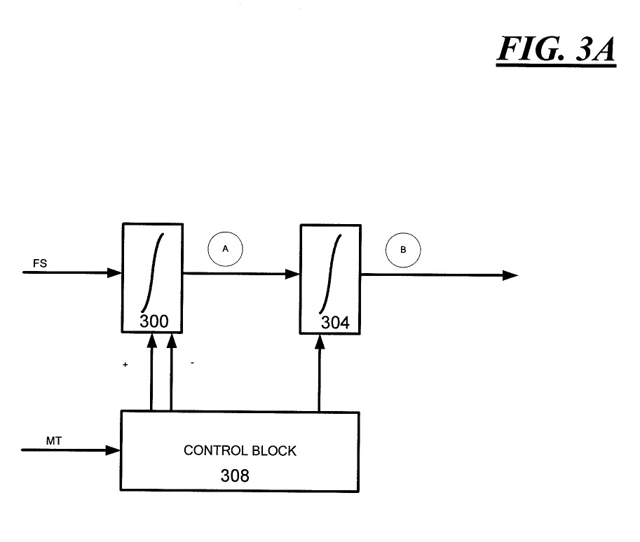

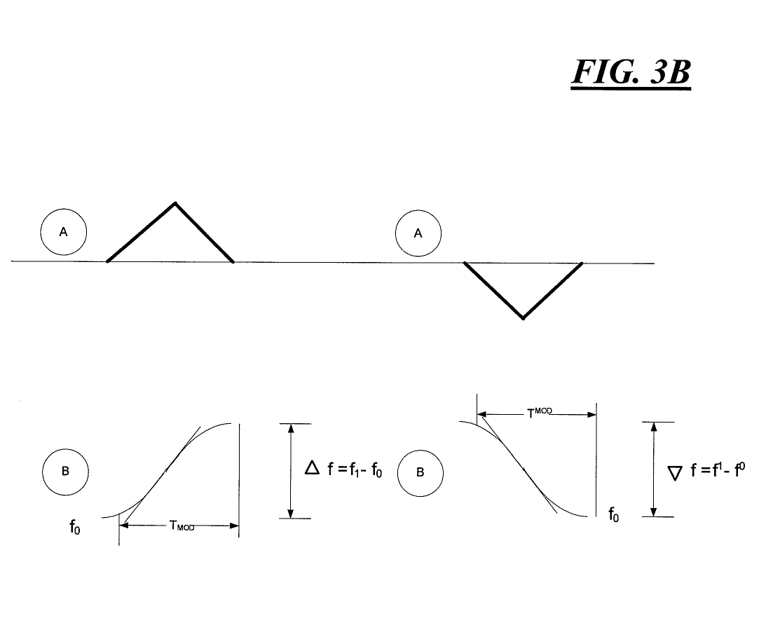

Two parameters characterize the parabolic approximation of the raised cosine curve in terms of its magnitude, reflected in the frequency separation used in the GFSK modulation, and its duration, which determines the transition time between the two frequency levels used in the GFSK modulation. With reference to FIG. 3A, the first parameter is referred to as the frequency separation parameter (FS) and the second parameter is referred to as the modulation time parameter (MT).

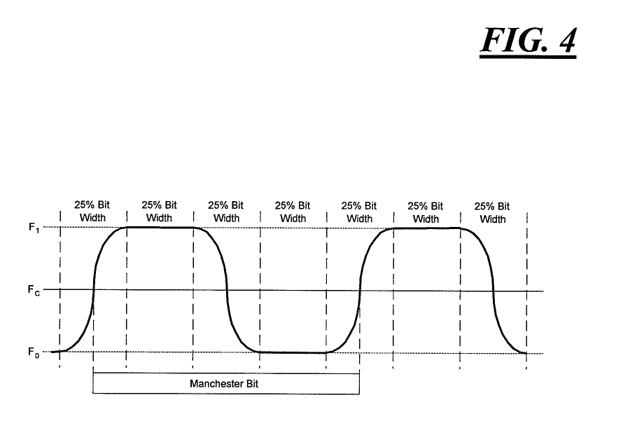

With further reference to FIG. 3A, a raised cosine generator may be implemented using a first integrator 300 and a second integrator 304 connected in series, each in communication with a control block 308. As illustrated in FIG. 3B, under the control of the control block 308 the first integrator 300 integrates the programmable constant FS during the first half of the time set by the constant MT to generate the positive frequency deviation for FSK transmission. During the second half of the time set by the constant MT, the integrator 300 integrates the negative value of programmable constant FS to complete the positive frequency deviation. For a negative frequency deviation, the integrator 300 similarly integrates the negative and then the positive value of MT. The waveforms provided at the (A) output of integrator 300 and the (B) output of integrator 304 in operation are presented in FIG. 3B. FIG. 4 presents an example of Manchester encoded data provided by the transmitter.

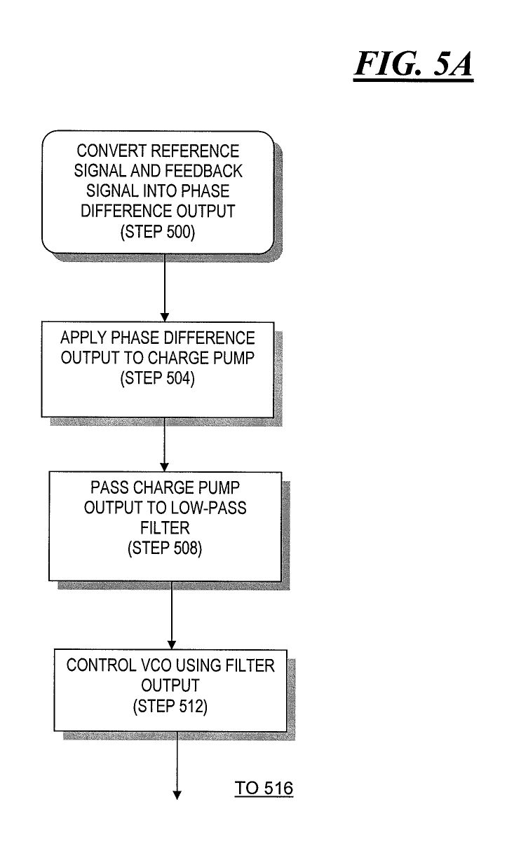

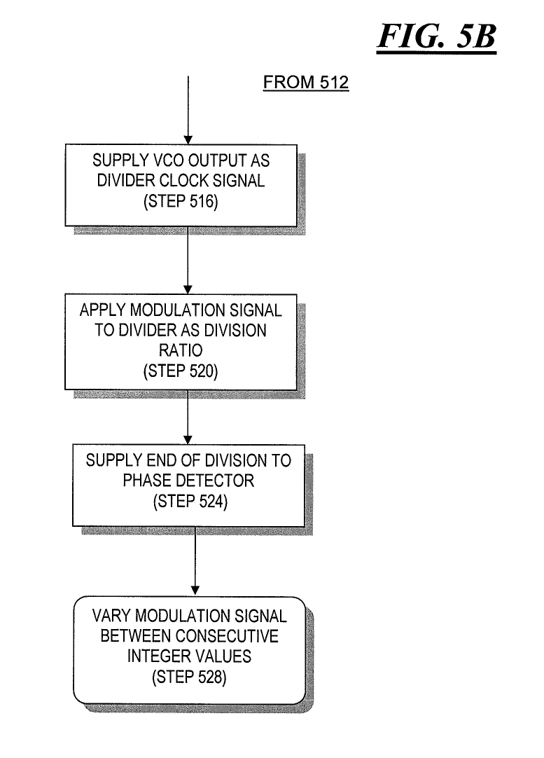

With reference to FIGS. 5A & 5B, embodiments of the present invention also provide methods for frequency shift keying using direct modulation. In one embodiment, a reference signal and a feedback signal are converted into a phase difference output (Step 500) using, e.g., a phase detector. This signal is applied to a charge pump (Step 504), and the output of the charge pump is passed to a low-pass filter (Step 508). The output signal from the low-pass filter controls a voltage-controlled oscillator (Step 512), and the output frequency signal from the VCO is used as a clock signal for a divider (Step 516). A modulation signal serving as a changing division ratio coefficient is applied to the divider as the division ratio (Step 520), and the end of the division signal is supplied as the feedback signal to the phase detector (Step 524).

The modulation signal is varied between consecutive integer values so as to realize a divider with a division ratio that on average is a non-integer multiple of the reference frequency (Step 528), forming a so-called fractional-N phased locked loop. The modulation signal may be generated by adding a constant value representing the integer part of non-integer N, and the changing value from the output a high-order sigmal-delta modulator, which is a sequential integer representing the results of a sigma-delta modulation of a fractional part of a non-integer N.

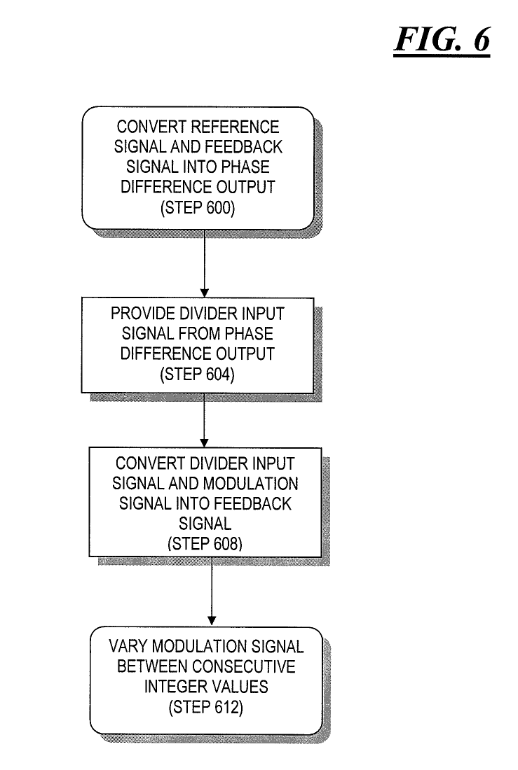

FIG. 6 presents another embodiment of a method for frequency shift keying using direct modulation. In one embodiment, a reference signal and a feedback signal are converted into a phase difference output (Step 600) using, e.g., a phase detector. A divider input signal is provided from the phase difference output (Step 604) using, e.g., a voltage-controlled oscillator. Together with a modulation signal, the divider input signal is converted into the feedback signal (Step 608). The modulation signal is varied between consecutive integer values so as to realize a divider input signal that is a non-integer multiple of the reference frequency (Step 612).

The modulation signal may be varied between consecutive integer values using stitched together parabolic curves, and may be provided using a sigma-delta stage, e.g., of third order or greater. The output of the sigma-delta stage may be summed with the output of a raised cosine generator. A filtered output may be provided from the phase difference output using a filter. The phase difference output may be received from the phase detector at a charge pump and provided to the filter. The divider input signal may be received at an antenna, or at a power amplifier and then in turn at an antenna. The reference signal may be derived from a thermally-controlled oscillator.

It will therefore be seen that the foregoing represents a highly advantageous approach to the transmission of digital signals. The terms and expressions employed herein are used as terms of description and not of limitation and there is no intention, in the use of such terms and expressions, of excluding any equivalents of the features shown and described or portions thereof, but it is recognized that various modifications are possible within the scope of the invention claimed. For example, it is well within the scope of the claimed invention to utilize the apparatus and methods of the present invention and equivalents thereof for the transmission of analog or digital signals.

What is claimed is:

1. A modulator comprising:
a phase detector receiving a reference signal and a feedback signal and providing a phase difference output;
a charge pump receiving the phase difference output from the phase detector and providing the phase difference output to the filter;
a filter receiving the phase difference output from the phase detector and providing the phase difference output to a voltage-controlled oscillator;
a voltage-controlled oscillator receiving the phase difference output and providing a divider input signal; and
a divider receiving the divider input signal and a modulation signal and providing the feedback signal,
wherein the modulation signal is varied between consecutive integer values using stitched together parabolic curves so as to realize a divider input signal that is a non-integer multiple of the reference frequency.

2. The modulator of claim 1 further comprising a transmitter coupled to the modulator having an antenna receiving the divider input signal.

3. The modulator of claim 1 further comprising a transmitter coupled to the modulator having a power amplifier receiving the divider input signal from the voltage-controlled oscillator and providing the divider input signal to the antenna.

4. The modulator of claim 1 wherein the reference signal is derived from a thermally-controlled oscillator.

5. The modulator of claim 1 wherein the modulation signal is provided by a sigma-delta stage.

6. The modulator of claim 5 wherein the sigma-delta stage is at least third order.

7. The modulator of claim 1 wherein the modulation signal is provided by an adder summing the constant value representing the integer part of non-integer N and the changing value from the output of a sigma-delta stage and where the input signal of the sigma-delta stage is an output signal of a second adder.

8. The modulator of claim 7 wherein the inputs of the second adder are a constant, representing the fractional part of a non-integer N, and another digital signal from the output of a raised cosine generator changing according to an approximation of a raised cosine law using two stitched-together parts of parabolas that are in a point symmetry to each other.

9. The modulator of claim 8 wherein the raised cosine generator comprises a first integrator, a second integrator, and a control block.

10. A method for direct modulation, the method comprising:
converting a reference signal and a feedback signal into a phase difference output signal using a phase detector and applying this signal to a charge pump;
supplying the output signal of the charge pump to a low-pass filter;
controlling a voltage-controlled oscillator (VCO) with the output signal from the low-pass filter;
providing an output frequency signal from the VCO as a divider clock signal;
applying to a divider the divider clock signal and a modulation signal serving as a changing division ratio coefficient;
supplying the end of division signal as the feedback signal to the phase detector; and
varying the modulation signal between consecutive integer values so as to realize a divider with division ratio that on the average is a non-integer multiple of the reference frequency,
wherein the modulation signal is derived by adding the constant value representing the integer part of non-integer N to the changing value from the output of a sigma-delta modulation of a sum of a constant, representing the fractional part of a non-integer N, and another digital signal changing according to an approximation of a raised cosine law using two stitched-together parts of parabolas that are in a point symmetry to each other.

11. The method of claim 10 wherein the digital signal changing according to an approximation of a raised cosine law using two stitched-together parts of parabolas that are in a point symmetry to each other is provided from a raised cosine generator comprising a first integrator, a second integrator, and a control block.

12. A method for direct modulation, the method comprising:
converting a reference signal and a feedback signal into a phase difference output signal using a phase detector;
providing a divider input signal from the phase difference output using a voltage-controlled oscillator;
converting the divider input signal and a modulation signal into the feedback signal using a divider; and
varying the modulation signal between consecutive integer values using stitched together parabolic curves so as to realize a divider input signal that is a non-integer multiple of the reference frequency.

13. The method of claim 12 further comprising providing a filtered output from the phase difference output using a filter.

14. The method of claim 12 further comprising receiving the divider input signal at an antenna.

15. The method of claim 14 further comprising receiving the divider input signal from the voltage-controlled oscillator at a power amplifier and providing the divider input signal to the antenna.

16. The method of claim 13 further comprising receiving the phase difference output from the phase detector at a charge pump and providing the charge pump output to the filter.

17. The method of claim 12 further comprising deriving the reference signal from a thermally-controlled oscillator.

18. The method of claim 12 further comprising providing the modulation signal using a sigma-delta stage.

19. The method of claim 18 wherein the sigma-delta stage is at least third order.

20. The method of claim 13 further comprising providing the modulation signal at the input of a sigma-delta stage using an adder receiving inputs representing fractional part of the required division value and an output value from the raised cosine generator, and providing a summed output as the modulation input signal.

21. The method of claim 20 wherein providing the modulation input signal comprises providing a sum of inputs representing fractional part of the required division value and an output value from the raised cosine generator, the raised cosine generator comprising a first integrator, a second integrator, and a control block.
